(19) United States
(12) Patent Application Publication
(10) Pub. No.: US 2025/0221241 A1
(43) Pub. Date: Jul. 3, 2025

(54) DISPLAY DEVICE

(71) Applicant: LG Display Co., Ltd., Seoul (KR)

(72) Inventors: Dahye KWON, Seoul (KR); Sungbin SHIM, Yangsan-si (KR); JunHyeok YANG, Seoul (KR)

(73) Assignee: LG Display Co., Ltd., Seoul (KR)

(21) Appl. No.: 18/932,258

(22) Filed: Oct. 30, 2024

(30) Foreign Application Priority Data
Dec. 29, 2023 (KR) 10-2023-0196628

(51) Int. Cl. H10K 59/80; H10K 59/123; H10K 59/124; H10K 71/00; H10K 102/00; H10K 102/10

(52) U.S. Cl. CPC H10K 59/80517; H10K 59/123; H10K 59/80515; H10K 59/124; H10K 59/878; H10K 71/861; H10K 2102/103; H10K 2102/3026

(57) ABSTRACT

According to an aspect of the present disclosure, a display device can include a substrate, a transistor disposed on the substrate, an overcoating layer disposed on the transistor, a reflective layer disposed on the overcoating layer, an insulation layer disposed on the overcoating layer and the reflective layer, and an organic light-emitting element disposed on the insulation layer and electrically connected to the transistor. The organic light-emitting element can include an anode, a light-emitting part, and a cathode, in which the anode is made of a transparent conductive oxide and is a conductor as a whole.

### CROSS-REFERENCE TO RELATED APPLICATIONS

This application claims priority to Korean Patent Application No. 10-2023-0196628 filed on Dec. 29, 2023, in the Korean Intellectual Property Office, the entire contents of which is hereby expressly incorporated by reference into present application.

### BACKGROUND

### Field

The present disclosure relates to a display device, and more particularly, to a display device with improved repair reliability.

### Discussion of the Related Art

Unlike a liquid crystal display apparatus, an organic light-emitting display device does not require a separate light source and thus can be manufactured as a lightweight, thin display device. In addition, the organic light-emitting display device is advantageous in terms of power consumption because the organic light-emitting display device operates at a low voltage. Further, the organic light-emitting display device is studied as a next-generation display device since the organic light-emitting display device is excellent in color implementation, a response speed, a viewing angle, and a contrast ratio (CR).

The organic light-emitting display device refers to a display device that autonomously emits light. The organic light-emitting display device refers to a display device using an organic light-emitting element that injects electrons and holes into a light-emitting layer from a cathode for injecting the electrons and an anode for injecting the holes and emits light when excitons, which are made by coupling the injected electrons and holes, fall from an excited state to a ground state.

The organic light-emitting display devices can be classified into a top emission type display device, a bottom emission type display device, and a dual emission type display device depending on directions in which light is emitted. The organic light-emitting display devices can be classified into a passive matrix type display device and an active matrix type display device depending on operating methods.

### SUMMARY OF THE DISCLOSURE

An object to be achieved by the present disclosure is to provide a display device capable of improving repair reliability against a foreign substance defect.

Another object to be achieved by the present disclosure is to provide a display device capable of minimizing or preventing a repair failure without a separate additional process and optimizing a process with reduced production energy.

Objects of the present disclosure are not limited to the above-mentioned objects, and other objects, which are not mentioned above, can be clearly understood by those skilled in the art from the following descriptions.

A display device according to an embodiment of the present disclosure includes a substrate; a transistor disposed on the substrate; an overcoating layer disposed on the transistor; a reflective layer disposed on the overcoating layer; an insulation layer disposed on the overcoating layer and the reflective layer; and an organic light-emitting element disposed on the insulation layer, electrically connected to the transistor, and including an anode, a light-emitting part, and a cathode, in which the anode is made of a transparent conductive oxide and is a conductor as a whole.

A display device according to another embodiment of the present disclosure includes a substrate; a transistor disposed on the substrate; an overcoating layer disposed on the transistor; a reflective layer disposed on the overcoating layer; an insulation layer disposed on the overcoating layer and the reflective layer; and an organic light-emitting element disposed on the insulation layer, electrically connected to the transistor, and including an anode, a light-emitting part, and a cathode, in which the anode is made of a transparent conductive oxide and includes a low-resistance portion, and a high-resistance portion having a higher resistance value than the low-resistance portion.

Other detailed matters of the example embodiments of the present disclosure are included in the detailed description and the drawings.

According to the effects of the present disclosure, it is possible to minimize or prevent a limitation in which a repair process may fail because the first electrode and the second electrode are in contact with each other again as the second electrode is pushed during the repair process related to a foreign substance defect.

According to the effects of the present disclosure, an electrical disconnection between the first electrode and the second electrode can be maintained without an additional process, even though the second electrode is pushed after the repair process related to a foreign substance defect.

The effects according to aspects of the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a top plan view of a display device according to an embodiment of the present disclosure;

FIG. 2 is a cross-sectional view taken along line A-A′ in FIG. 1;

FIGS. 3A to 3E are views for explaining a process of manufacturing the display device according to the embodiment of the present disclosure;

FIGS. 4A and 4B are enlarged cross-sectional views of a portion of the display device according to the embodiment where a foreign substance defect occurs;

FIG. 5 is a cross-sectional view of a display device according to another embodiment of the present disclosure; and

FIG. 6 is a cross-sectional view of a display device according to still another embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as ‘including’, ‘having’, ‘consist of’ used herein are generally intended to allow other components to be added unless the terms are used with the term ‘only’. Any references to singular can include plural unless expressly stated otherwise.

Components are interpreted to include an ordinary error range even if not expressly stated.

When the position relation between two parts is described using the terms such as ‘on’, ‘above’, ‘below’, ‘next’, one or more parts can be positioned between the two parts unless the terms are used with the term ‘immediately’ or ‘directly’.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components, and may not define order or sequence. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated. Further, the term “can” fully encompasses all the meanings and coverages of the term “may.”

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to accompanying drawings. All the components of each display device according to all embodiments of the present disclosure are operatively coupled and configured.

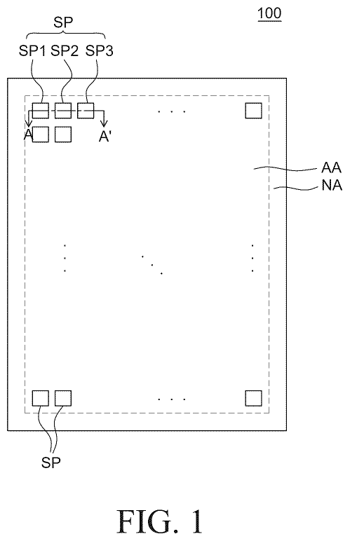

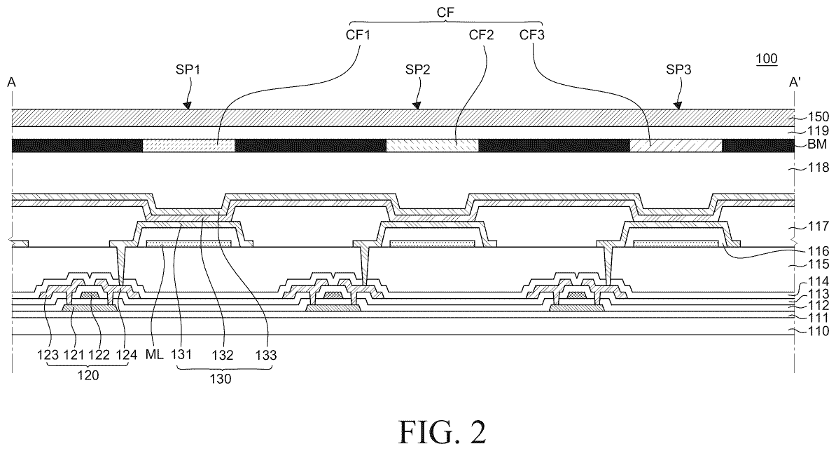

FIG. 1 is a top plan view of a display device according to an embodiment of the present disclosure. FIG. 2 is a cross-sectional view taken along line A-A′ in FIG. 1.

With reference to FIGS. 1 and 2, a display device 100 includes a lower substrate 110, transistors 120, organic light-emitting elements 130, and an upper substrate 150.

With reference to FIG. 1, the lower substrate 110 is configured to support and protect several constituent elements of the display device 100. The lower substrate 110 can be made of a plastic material having flexibility. In addition, the lower substrate 110 can be made of an insulating material with transparency. For example, the lower substrate 110 can be made of transparent polyimide (PI).

The lower substrate 110 includes a display area AA (or active area) and a non-display area NA (or non-active area). The non-display area NA can surround the display area AA entirely or only in part(s).

The display area AA can be disposed at a central portion of the lower substrate 110. The display area AA can be an area of the display device 100 in which images are displayed. Various display elements and various driving elements for operating the display elements can be disposed in the display area AA. For example, the display element can be configured as the organic light-emitting element 130 including a first electrode 131, a light-emitting part 132, and a second electrode 133. In addition, various driving elements such as transistors, capacitors, lines, and the like, which are configured to operate the display elements, can be disposed in the display area AA.

A plurality of subpixels SP can be disposed in the display area AA. The plurality of subpixels SP can each be an area in which a plurality of gate lines disposed in a first direction and a plurality of data lines disposed in a second direction different from the first direction intersect each other. In this case, the first direction can be a horizontal direction based on FIG. 1, and the second direction can be a vertical direction based on FIG. 1. However, the present disclosure is not limited thereto. The plurality of subpixels SP can include a plurality of first subpixels SP1, a plurality of second subpixels SP2, and a plurality of third subpixels SP3 that emit light beams with different colors. For example, the plurality of first subpixels SP1 can be red subpixels, the plurality of second subpixels SP2 can be green subpixels, and the plurality of third subpixels SP3 can be blue subpixels. However, the plurality of subpixels SP can further include a fourth subpixel that is a white subpixel. However, the present disclosure is not limited thereto.

The subpixel SP is a minimum unit that constitutes a screen. The plurality of subpixels SP can each include the organic light-emitting element 130 and a driving element. The driving element can include a switching transistor, a driving transistor, and the like. The driving element can be electrically connected to signal lines such as gate lines and data lines connected to gate drivers and data drivers disposed in the non-display area NA.

The non-display area NA can be disposed in a peripheral area of the lower substrate 110. The non-display area NA can be an area in which no image is displayed. The non-display area NA can be disposed to surround the display area AA. Various constituent elements for operating the plurality of subpixels SP disposed in the display area AA can be disposed in the non-display area NA. For example, drive ICs, drive circuits, signal lines, flexible films, and the like, which are configured to supply signals for operating the plurality of subpixels SP, can be disposed. The drive IC can include a gate driver, a data driver, and the like. The drive IC and the drive circuit can be disposed by a gate-in-panel (GIP) method, a chip-on-film (COF) method, a tape automated bonding (TAB) method, a tape carrier package (TCP) method, a chip-on-glass (COG) method, and the like.

Hereinafter, the plurality of subpixels SP disposed in the display area AA of the display device 100 according to the embodiment of the present disclosure will be described in more detail with reference to FIG. 2.

With reference to FIGS. 1 and 2 together, the display device 100 according to the embodiment of the present disclosure can include the lower substrate 110, a buffer layer 111, a gate insulation layer 112, an interlayer insulation layer 113, a passivation layer 114, the transistor 120, an overcoating layer 115, a reflective layer ML, an insulation layer 116, the organic light-emitting element 130, a bank 117, an encapsulation layer 118, a color filter CF, a black matrix BM, a bonding member 119, and the upper substrate 150.

With reference to FIG. 2, the buffer layer 111 is disposed on the lower substrate 110. The buffer layer 111 can improve bonding forces between the lower substrate 110 and layers formed on the buffer layer 111. In addition, the buffer layer 111 can block a leak of alkaline material from the lower substrate 110 and inhibit moisture and/or oxygen penetrating from the outside of the lower substrate 110 from being diffused. The buffer layer 111 can be configured as a single layer or multilayer made of silicon nitride (SiNx) or silicon oxide (SiOx). However, the present disclosure is not limited thereto. In addition, the buffer layer 111 can be excluded depending on the type and material of the lower substrate 110, the structure and type of the transistor 120, and the like.

The transistor 120 can be disposed on the buffer layer 111 and operate the organic light-emitting element 130. The transistor 120 can be disposed in each of the plurality of subpixels SP in the display area AA. The transistor 120 disposed in each of the plurality of subpixels SP can be used as the driving element of the display device 100. For example, the transistor 120 can be a thin-film transistor (TFT), an N-channel metal oxide semiconductor (NMOS) transistor, a P-channel metal oxide semiconductor (PMOS) transistor, a complementary metal oxide semiconductor (CMOS) transistor, a field effect transistor (FET), or the like. However, the present disclosure is not limited thereto. Hereinafter, the description will be made on the assumption that the transistor 120 is the thin-film transistor. However, the present disclosure is not limited thereto.

The transistor 120 includes an active layer 121, a gate electrode 122, a source electrode 123, and a drain electrode 124. The transistor 120 illustrated in FIG. 2 is a thin-film transistor having a top-gate structure in which the gate electrode 122 is disposed on the active layer 121. However, the present disclosure is not limited thereto. The transistor 120 can be implemented as a thin-film transistor having a bottom-gate structure.

The active layer 121 of the transistor 120 is disposed on the buffer layer 111. The active layer 121 is an area in which a channel is formed when the transistor 120 operates. The active layer 121 can be made of an oxide semiconductor, amorphous silicon (a-Si), polycrystalline silicon (poly-Si), an organic semiconductor, or the like. However, the present disclosure is not limited thereto.

The gate insulation layer 112 is disposed on the active layer 121. The gate insulation layer 112 can be configured as a single layer or multilayer made of silicon nitride (SiNx) or silicon oxide (SiOx) that is an inorganic material. The gate insulation layer 112 has contact holes through which the source electrode 123 and the drain electrode 124 are in contact with a source area and a drain area of the active layer 121, respectively. As illustrated in FIG. 2, the gate insulation layer 112 can be formed over the entire surface of the lower substrate 110 or patterned to have the same width as the gate electrode 122. However, the present disclosure is not limited thereto.

The gate electrode 122 is disposed on the gate insulation layer 112. The gate electrode 122 is disposed on the gate insulation layer 112 and overlaps the channel area of the active layer 121. The gate electrode 122 can be made of any one of various metallic materials, for example, molybdenum (Mo), aluminum (Al), chromium (Cr), gold (Au), titanium (Ti), nickel (Ni), neodymium (Nd), copper (Cu), or an alloy of two or more of these metallic materials. Alternatively, the gate electrode 122 can be configured as a multilayer made of various metallic materials, for example, molybdenum (Mo), aluminum (Al), chromium (Cr), gold (Au), titanium (Ti), nickel (Ni), neodymium (Nd), copper (Cu), or an alloy of two or more of these metallic materials. However, the present disclosure is not limited thereto.

The interlayer insulation layer 113 is disposed on the gate electrode 122. The interlayer insulation layer 113 can be configured as a single layer or multilayer made of silicon nitride (SiNx) or silicon oxide (SiOx) that is an inorganic material. The interlayer insulation layer 113 has contact holes through which the source electrode 123 and the drain electrode 124 are in contact with the source area and the drain area of the active layer 121, respectively.

The source electrode 123 and the drain electrode 124 are disposed on the interlayer insulation layer 113. The source electrode 123 and the drain electrode 124 are electrically connected to the active layer 121 through the contact holes of the gate insulation layer 112 and the contact holes of the interlayer insulation layer 113. The source electrode 123 and the drain electrode 124 can each be made of any one of various metallic materials, for example, molybdenum (Mo), aluminum (Al), chromium (Cr), gold (Au), titanium (Ti), nickel (Ni), neodymium (Nd), copper (Cu), or an alloy of two or more of these metallic materials. Alternatively, the source electrode 123 and the drain electrode 124 can each be configured as a multilayer made of various metallic materials, for example, molybdenum (Mo), aluminum (Al), chromium (Cr), gold (Au), titanium (Ti), nickel (Ni), neodymium (Nd), copper (Cu), or an alloy of two or more of these metallic materials. However, the present disclosure is not limited thereto.

For convenience of description, FIG. 2 illustrates the driving transistor among various transistors 120 included in the display device 100. However, the other transistors such as a switching transistor can be disposed.

With reference to FIG. 2, the passivation layer 114 for protecting the transistor 120 is disposed on the transistor 120. The passivation layer 114 has a contact hole through which the drain electrode 124 of the transistor 120 is exposed. FIG. 2 illustrates that the contact hole is formed in the passivation layer 114 in order to expose the drain electrode 124. However, a contact hole can be formed to expose the source electrode 123. The passivation layer 114 can be configured as a single layer or multilayer made of silicon nitride (SiNx) or silicon oxide (SiOx). However, the passivation layer 114 can be excluded in accordance with the embodiments.

The overcoating layer 115 for planarizing an upper portion of the transistor 120 is disposed on the passivation layer 114. The overcoating layer 115 has a contact hole through which the drain electrode 124 of the transistor 120 is exposed. FIG. 2 illustrates that the contact hole is formed in the overcoating layer 115 in order to expose the drain electrode 124. However, a contact hole can be formed to expose the source electrode 123. The overcoating layer 115 can be made of one of acrylic resin, epoxy resin, phenol resin, polyamide resin, polyimide resin, unsaturated polyester resin, polyphenylene resin, polyphenylene sulfide resin, benzocyclobutene, and a photoresist. However, the present disclosure is not limited thereto.

The reflective layer ML is disposed on the overcoating layer 115. The reflective layer ML is disposed in each of the plurality of subpixels SP. The reflective layer ML is disposed to correspond to each of the first electrodes 131 of the organic light-emitting elements 130 disposed in the plurality of subpixels SP. The reflective layers ML disposed in the plurality of subpixels SP are disposed to be spaced apart from one another. Therefore, the reflective layer ML is disposed at an outer periphery of each of the plurality of subpixels SP and exposes a top surface of the overcoating layer 115.

The reflective layer ML is disposed below the first electrode 131 of the organic light-emitting element 130 in each of the plurality of subpixels SP. The reflective layer ML is electrically floated. For example, the reflective layer ML can be configured so as not to be electrically connected to other constituent elements such as the organic light-emitting element 130 and the transistor 120. The reflective layer ML is disposed to allow the light, which is emitted from the light-emitting part 132, to propagate toward the upper side of the display device 100. For example, the reflective layer ML can be made of a reflective metallic material including silver (Ag) and configured as a multilayer. However, the present disclosure is not limited thereto.

The insulation layer 116 is disposed on the overcoating layer 115 and the reflective layer ML. The insulation layer 116 is disposed on the top surface of the overcoating layer 115 exposed from the reflective layer ML, and the insulation layer 116 is disposed to cover side and top surfaces of the reflective layer ML. The insulation layer 116 electrically insulate the reflective layer ML and the first electrode 131.

For example, the insulation layer 116 can be made of an inorganic insulating material, such as silicon nitride (SiNx) or silicon oxide (SiOx), or an organic insulating material, such as acrylic resin, epoxy resin, phenol resin, polyamide resin, polyimide resin, unsaturated polyester resin, polyphenylene resin, polyphenylene sulfide resin, benzocyclobutene, and a photoresist. However, the present disclosure is not limited thereto.

The organic light-emitting element 130 is disposed on the overcoating layer 115 and the insulation layer 116. The organic light-emitting element 130 includes the first electrode 131 formed on the overcoating layer 115 and the insulation layer 116 and electrically connected to the drain electrode 124 of the transistor 120, the light-emitting part 132 disposed on the first electrode 131, and the second electrode 133 formed on the light-emitting part 132. In this case, the first electrode 131 can be an anode electrode, and the second electrode 133 can be a cathode electrode.

The first electrode 131 is disposed on the overcoating layer 115 and the insulation layer 116. The first electrode 131 is disposed to cover the top surface of the overcoating layer 115 and the side and top surfaces of the insulation layer 116. The first electrode 131 is electrically connected to the drain electrode 124 of the transistor 120 through the contact hole formed in the passivation layer 114 and the overcoating layer 115. For example, the first electrode 131 can be electrically connected to the transistor 120 while being in direct contact with the transistor 120. Therefore, the organic light-emitting element 130 can be connected to the transistor 120.

FIG. 2 illustrates that the first electrode 131 is electrically connected to the drain electrodes 124 of the transistors 120 through the contact hole. However, the first electrode 131 can be electrically connected to the source electrode 123 of the transistor 120 through a contact hole in accordance with the type of transistor 120, a method of designing the drive circuit, and the like.

The first electrode 131 can be made of a transparent conductive oxide. For example, the first electrode 131 can be made of a transparent conductive oxide, such as indium zinc oxide (IZO) and indium gallium zinc oxide (IGZO), including indium (In). However, the present disclosure is not limited thereto.

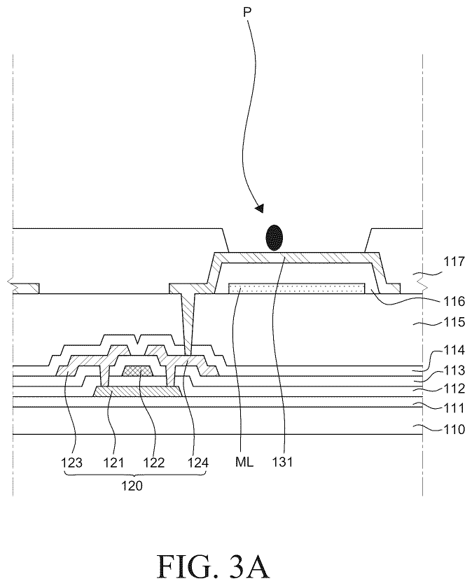

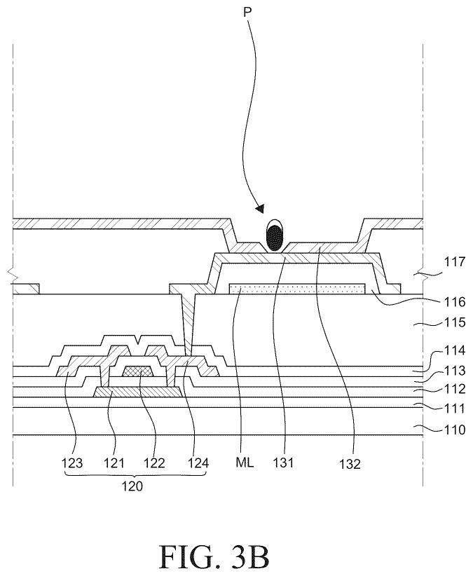

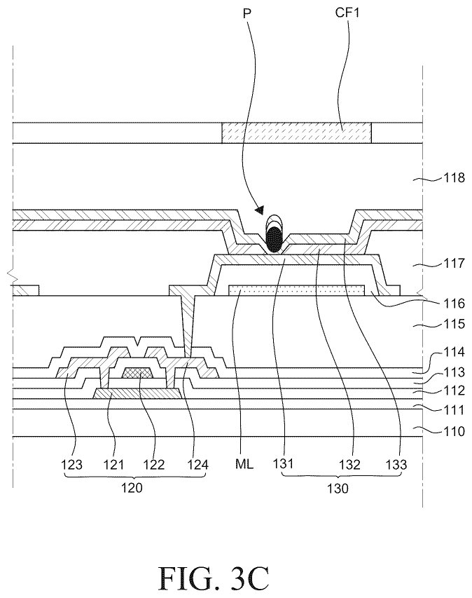

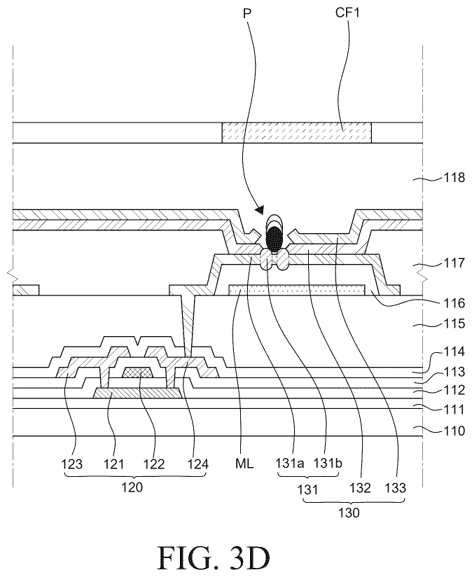

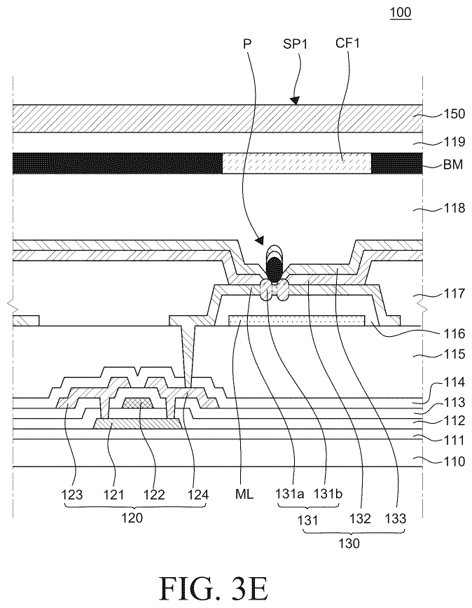

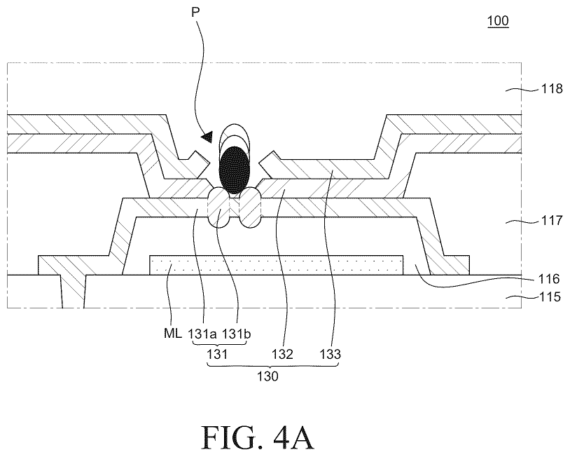

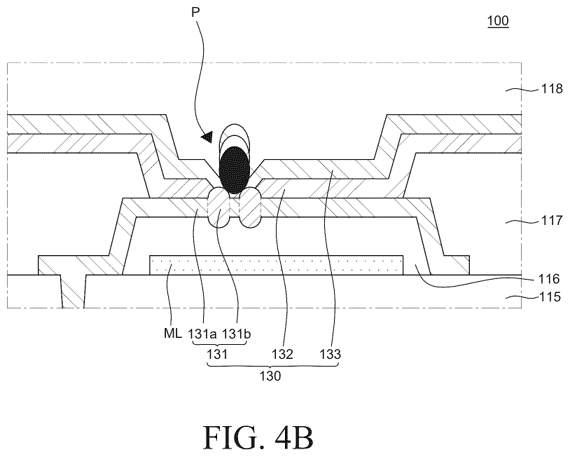

In addition, the first electrode 131 can be configured to be partially electrically disconnected and thus serve as a repair part that repairs the subpixel SP with a foreign substance defect. However, a method of repairing subpixel SP with a foreign substance defect will be described below in detail with reference to FIGS. 3A to 4B.

Meanwhile, FIG. 2 illustrates normal subpixels SP that do not have a foreign substance defect and are not subjected to the repair process. In this case, because the first electrodes 131 disposed in the subpixels SP, which do not have a foreign substance defect, are not subjected to the repair process, all the first electrodes 131 can be conductors.

The bank 117 is disposed on the first electrode 131 and the overcoating layer 115. The bank 117 can cover an edge of the first electrode 131 of the organic light-emitting element 130 and define a light-emitting area. The bank 117 can be disposed between the adjacent subpixels SP to reduce a color mixture of the light beams emitted from the organic light-emitting elements 130 in the plurality of subpixels SP.

The bank 117 can be made of an organic material. For example, the bank 117 can be made of polyimide resin, acrylic resin, or benzocyclobutene resin. However, the present disclosure is not limited thereto.

The light-emitting part 132 is disposed on the first electrode 131 and the bank 117. For example, the light-emitting part 132 can be a light-emitting layer that emits light with any one color among red, green, blue, and white. In addition, the light-emitting part 132 can further include various layers such as a hole transport layer, a hole injection layer, a hole blocking layer, an electron injection layer, an electron blocking layer, and an electron transport layer. However, the present disclosure is not limited thereto.

The second electrode 133 is disposed on the light-emitting part 132. The second electrode 133 can supply electrons to the light-emitting part 132. The second electrode 133 can be made of an electrically conductive material with a low work function. The second electrode 133 can be configured to allow the light, which is emitted from the light-emitting part 132, to propagate toward the upper side of the display device 100. For example, the second electrode 133 can be made of a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

Meanwhile, an inorganic insulation layer for protecting the second electrode 133 can be further disposed on the second electrode 133. For example, the inorganic insulation layer can be configured as a single layer or multilayer made of silicon nitride (SiNx) or silicon oxide (SiOx). However, the present disclosure is not limited thereto.

With reference to FIG. 2, the encapsulation layer 118 is disposed on the organic light-emitting element 130. The encapsulation layer 118 can cover the organic light-emitting element 130. The encapsulation layer 118 can protect the organic light-emitting element 130 from external moisture, oxygen, impact, and the like. The encapsulation layer 118 can be formed by alternately stacking a plurality of inorganic layers and a plurality of organic layers. For example, the inorganic layer can be made of an inorganic material such as silicon nitride (SiNx), silicon oxide (SiOx), or aluminum oxide (AlOx). The organic layer can be made of epoxy-based polymer or acrylic polymer. However, the present disclosure is not limited thereto.

The color filter CF and the black matrix BM are disposed on the encapsulation layer 118.

The color filter CF can be disposed in each of the plurality of subpixels SP. The black matrix BM can be disposed at a boundary between the plurality of subpixels SP. Therefore, the black matrix BM can separate the plurality of subpixels SP and the color filters CF disposed in the subpixels SP, thereby reducing a color mixture between the plurality of subpixels SP.

For example, in case that the light emitted from the light-emitting part 132 is white light, the color filters CF convert the light emitted from the subpixels SP into red light, green light, and blue light. For example, a first color filter CF1, which is disposed in the first subpixel SP1 that is a red subpixel, can be a red color filter. In addition, a second color filter CF2, which is a green color filter, can be disposed in the second subpixel SP2 that is a green subpixel, and a third color filter CF3, which is a blue color filter, can be disposed in the third subpixel SP3 that is a blue subpixel. However, the present disclosure is not limited thereto.

For example, the black matrix BM can be made of chromium (Cr) or other opaque metal films or made of resin. However, the present disclosure is not limited thereto.

The upper substrate 150 is disposed above the color filter CF and the black matrix BM. The upper substrate 150, together with the encapsulation layer 118, can protect the organic light-emitting element 130 from external moisture, oxygen, impact, and the like. For example, the upper substrate 150 can be made of a transparent insulating material, and the display device 100 can be configured as a top emission type display device 100. However, the present disclosure is not limited thereto.

The bonding member 119 is disposed between the color filter CF, the black matrix BM, and the upper substrate 150. The bonding member 119 can bond the color filter CF, the black matrix BM, and the upper substrate 150. The bonding member 119 can be made of a material having bondability. The bonding member 119 can be a thermosetting or naturally curable bonding agent. For example, the bonding member 119 can be an optical clear adhesive (OCA), a pressure sensitive adhesive (PSA), or the like. However, the present disclosure is not limited thereto.

Hereinafter, a process of manufacturing the display device according to the embodiment of the present disclosure and a method of repairing a subpixel with a defect which can be caused by foreign substances during the process of manufacturing the display device will be described in more detail with reference to FIGS. 3A to 4B.

Particularly, FIGS. 3A to 3E are views for explaining a process of manufacturing the display device according to the embodiment of the present disclosure. FIGS. 4A and 4B are enlarged cross-sectional views of a portion of the display device according to the embodiment where a foreign substance defect occurs.

For example, during the process of manufacturing the display device, a short circuit (A-C short circuit) can occur between the anode and the cathode by foreign substances remaining between the anode and the cathode of the organic light-emitting element. Therefore, a dark spot defect can occur in which an electric current is not applied to the organic light-emitting element. Therefore, a repair process can be performed to separate the cathode from the anode when the cathode is connected to the anode by foreign substances produced during the manufacturing process. For example, the repair process can include an R2-aging process of separating the cathode from the anode by applying a high voltage to the cathode.

With reference to FIGS. 3A to 3E, the display device 100 according to the embodiment of the present disclosure is configured to repair a subpixel with a defect which can be caused by foreign substances during the manufacturing process.

First, with reference to FIG. 3A, the transistor 120 is disposed on the lower substrate 110. The passivation layer 114 for protecting the transistor 120 is disposed on the transistor 120, and the overcoating layer 115 for planarizing the upper portion of the transistor 120 is disposed on the transistor 120. The reflective layer ML is disposed on the overcoating layer 115, and the insulation layer 116 for insulating the reflective layer is disposed on the overcoating layer 115. In this case, the insulation layer 116 is disposed to expose the top surface of the overcoating layer 115. Further, the contact holes are formed in the passivation layer 114 and the overcoating layer 115 to expose a part of the drain electrode 124 of the transistor 120, and the first electrode 131 of the organic light-emitting element 130 is disposed on the exposed part of the drain electrode 124 so as to be connected to the transistor 120. Next, the bank 117 is disposed to cover the edge of the first electrode 131. The bank 117 can be disposed on the top surface of the overcoating layer 115 and the first electrode 131 to expose a part of the top surface of the first electrode 131.

Meanwhile, foreign substances P can be attached to the surface of the first electrode 131 exposed by the bank 117. For example, the foreign substances P can be produced by a process of patterning a material for forming the first electrode 131 or a process of etching an insulating material layer for forming the bank 117. However, the present disclosure is not limited thereto.

Next, with reference to FIG. 3B, the light-emitting part 132 is disposed on the first electrode 131 and the bank 117. The light-emitting part 132 can be continuously disposed on the top surface of the first electrode 131 and the side and top surfaces of the bank 117 and disposed in all the plurality of subpixels SP. Meanwhile, in a portion where the foreign substances P are disposed, a portion can occur where the light-emitting part 132 cannot cover the top surface of the first electrode 131 because of the foreign substances P. For example, the top surface of the first electrode 131 can be exposed by the light-emitting part 132. However, in case that a thickness of the foreign substance P is much smaller than a thickness of the light-emitting part 132, the foreign substance P may not affect constituent elements to be stacked during a subsequent process. However, the present disclosure is not limited thereto.

Next, with reference to FIG. 3C, the second electrode 133 is disposed on the light-emitting part 132. The second electrode 133, together with the light-emitting part 132, can be disposed in all the plurality of subpixels SP. Various constituent elements, except for the upper substrate 150 for sealing the display device 100, are disposed above the second electrode 133. For example, the encapsulation layer 118, the color filter CF1, and the black matrix BM are disposed above the second electrode 133. However, FIG. 3C illustrates that the color filter CF1 and the black matrix BM are disposed on the encapsulation layer 118 during the process of manufacturing the display device 100. However, the color filter CF and the black matrix BM can be disposed on the encapsulation layer 118 during a process of joining the upper substrate 150 and the lower substrate 110 after forming the color filter CF and the black matrix BM on the upper substrate 150. However, the present disclosure is not limited thereto.

In this case, the second electrode 133, which is disposed on the light-emitting part 132, can have an opening portion where the second electrode 133 cannot be disposed because of the foreign substances P. Meanwhile, the second electrode 133 is disposed even on the top surface of the first electrode 131 exposed by the light-emitting part 132. Because the first electrode 131 and the second electrode 133, which are in contact with each other, are electrically connected as described above, a short circuit can occur when the display device operates. For example, an A-C short circuit can be caused by the foreign substance P attached to the top surface of the first electrode 131.

Therefore, with reference to FIG. 3D, after the process of forming various constituent elements of the display device 100 except for the upper substrate 150, a process of repairing the second electrode 133 connected to the first electrode 131 is performed. For example, the process of repairing the second electrode 133 connected to the first electrode 131 can use an R2-aging method that separates the first electrode 131 and the second electrode 133 by deforming the first electrode 131 and the second electrode 133 by using a high electric current concentrated on a portion where the second electrode 133 and the first electrode 131 are in contact with each other by applying a high voltage to the second electrode 133. In this case, the second electrode 133, which is deformed by a high electric current, can be opened at a peripheral portion of the foreign substance P. Further, an end of the second electrode 133 in the opened portion can be disposed in a direction away from the first electrode 131, i.e., disposed in a shape directed upward. However, the present disclosure is not limited thereto.

Meanwhile, because resistance heat (Joule heating) is generated by a concentrated high electric current in a portion where the second electrode 133 and the first electrode 131 are in contact with each other during the R2-aging process, a high-resistance portion 131b can be formed on the first electrode 131. The high-resistance portion 131b can be formed by a process in which a diffusion phenomenon in which distances between indium (In) particles included in the first electrode 131 are increased by a high temperature occurs and a volume of the corresponding portion is also increased. In this case, a portion of the first electrode 131, where the high-resistance portion 131b is not formed, can be referred to as a low-resistance portion 131a. For example, a thickness of the high-resistance portion 131b can be larger than a thickness of the low-resistance portion 131a. The thickness of the high-resistance portion 131b can be increased by about 10% to 20% in comparison with the low-resistance portion 131a. However, the present disclosure is not limited thereto.

Meanwhile, an indium (In) density of the high-resistance portion 131b, which is a portion where the distances between the indium (In) particles are increased, can be lower than an indium density (In) of the low-resistance portion 131a. For example, the indium (In) density of the low-resistance portion 131a can be higher than the indium (In) density of the high-resistance portion 131b.

The high-resistance portion 131b can have a higher resistance value than the low-resistance portion 131a. For example, in case that the first electrode 131 is made of indium zinc oxide (IZO), oxygen (O₂) can be adsorbed by the first electrode 131 by a high temperature, and the first electrode 131 can be crystallized and oxidized, which can increase the resistance value. In this case, in case that the first electrode 131, which is made of indium zinc oxide (IZO), is heat-treated by resistance heat of 350° C. or more, the first electrode 131 can have surface resistance (Rs) of 1.4×10\hat{ }4Ω or more. In case that the first electrode 131 is heat-treated at 450° C. or more, the first electrode 131 can have surface resistance (Rs) of 1.64×10\hat{ }4Ω or more. Meanwhile, the surface resistance (Rs) of the low-resistance portion 131a, which is the portion to which resistance heat is not applied, can be about 4.67×10\hat{ }(−4)Ω or lower. For example, in comparison with the low-resistance portion 131a, the resistance value of the high-resistance portion 131b can be remarkably increased, and the movement of the electric current can also be decreased. Therefore, in the high-resistance portion 131b, the electrical connection can be substantially blocked.

Lastly, with reference to FIG. 3E, after the process of repairing the second electrode 133 connected to the first electrode 131, the bonding member 119 and the upper substrate 150 are joined and disposed above various constituent elements of the second electrode 133 and the display device 100 and seal the constituent elements of the display device 100, such that the process of manufacturing the display device 100 is completed.

In this case, the second electrode 133 spaced apart from the first electrode 131 can be pushed during the process of joining the upper substrate 150 and the second electrode 133, such that the first electrode 131 and the second electrode 133 can be disposed to adjoin each other again. In addition, in case that physical deformation of the second electrode 133 for separating the first electrode 131 and the second electrode 133 is not smoothly performed during the repair process, the first electrode 131 and the second electrode 133 can be disposed still in the state in which the first electrode 131 and the second electrode 133 adjoin each other. However, in the display device 100 according to the embodiment of the present disclosure, the high-resistance portion 131b is disposed on the first electrode 131 and surrounds at least a part of a peripheral portion of the foreign substance P during the process of repairing the second electrode 133 connected to the first electrode 131. Therefore, even though the first electrode 131 and the second electrode 133 are not separated from each other or the first electrode 131 and the second electrode 133 adjoin each other as the first electrode 131 is pushed against the second electrode 133 even after the repair process, the second electrode 133 adjoins the high-resistance portion 131b of the first electrode 131, such that the electrical connection between the second electrode 133 and the first electrode 131 can be substantially blocked.

Meanwhile, with reference to FIGS. 4A and 4B, in the display device 100 in a final product state, the second electrode 133 can be disposed on the first electrode 131 and spaced apart from the first electrode 131, as illustrated in FIG. 4A, or the second electrode 133 can be disposed to adjoin the high-resistance portion 131b, as illustrated in FIG. 4B. The case in which the second electrode 133 is disposed to be spaced apart from the first electrode 131 in the display device 100 in the final product state, as illustrated in FIG. 4A, in a case in which the second electrode 133 is not pushed during the process of joining the upper substrate 150. Further, the case in which the second electrode 133 is disposed to adjoin the high-resistance portion 131b, as illustrated in FIG. 4B, is a case in which the first electrode 131 and the second electrode 133 are not spaced apart from each other even after the repair process or the second electrode 133 is pushed during the process of joining the upper substrate 150. During the process of manufacturing the display device 100, the second electrode 133 can be disposed in any one of the shapes in FIGS. 4A and 4B in accordance with the manufacturing process. However, in both the two cases, the first electrode 131 and the second electrode 133 can be configured so as not to be electrically connected to each other.

Therefore, in the display device 100 according to the embodiment of the present disclosure, even though the first electrode 131 and the second electrode 133 are not spaced apart from each other even after the repair process related to the foreign substance defect or the second electrode 133 is pushed after the repair process, the electrical disconnection between the first electrode 131 and the second electrode 133 can be maintained without an additional process, such that a repair failure can be minimized without a separate additional process.

With reference to FIGS. 4A and 4B, the first electrode 131 and the reflective layer ML can be spaced apart from each other and electrically insulated by the insulation layer 116. Therefore, the reflective layer ML may not be damaged during the process of disposing the high-resistance portion 131b on the first electrode 131. For example, in case that the first electrode 131 is disposed on the reflective layer ML so as to be in direct contact with the reflective layer ML, the reflective layer ML, which is in contact with the first electrode 131, can be deformed by resistance heat generated when the high electric current is concentrated on the portion where the second electrode 133 and the first electrode 131 are in contact with each other during the R2-aging process, and the light reflection properties of the reflective layer ML can be degraded. In this case, in the display device 100 according to the embodiment of the present disclosure, the first electrode 131 and the reflective layer ML are spaced apart from each other by the insulation layer 116, such that the reflective layer ML may not be in direct contact with the second electrode 133. Therefore, it is possible to minimize damage to the reflective layer ML during the process of disposing the high-resistance part 131b on the first electrode 131 during the repair process.

For example, during the process of manufacturing the display device, a short circuit (A-C short circuit) can occur between the anode and the cathode by foreign substances remaining between the anode and the cathode of the organic light-emitting element. Therefore, a dark spot defect can occur in which an electric current is not applied to the organic light-emitting element. The repair process of separating the cathode from the anode when the cathode is connected to the anode by the foreign substance produced during the manufacturing process can be performed by selectively repairing only the portion of the anode and the cathode of the light-emitting element where a defect can be caused by foreign substances. For example, the repair process can include the R2-aging process of separating the cathode from the anode by applying a high voltage to the cathode. The above-mentioned repair process is advantageous in minimizing a non-light emission area by the repair process in comparison with a repair method of disposing a plurality of light-emitting elements in one subpixel and blocking only the connection of a defective light-emitting element.

However, after the R2-aging process, the anode and the cathode can adjoin each other again as the end of the cathode, which has been spaced apart from the anode, is pushed during the process of joining the upper substrate 150, and the anode and the cathode are short-circuited again as the cathode is pushed as described above. For this reason, there can occur a problem in that the repair process fails.

Therefore, in the display device 100 according to the embodiment of the present disclosure, the electrical connection of the first electrode 131 can be partially blocked, which can improve the reliability of the repair process related to the foreign substance defect.

Specifically, the first electrode 131 can be made of a transparent conductive oxide. Further, the process of repairing the A-C short circuit, which can be caused when the first electrode 131 and the second electrode 133 adjoin each other by the foreign substance P, is performed by applying a high voltage to the second electrode 133 during the process of manufacturing the display device 100. In this case, a high electric current can be concentrated between the first electrode 131 and the second electrode 133 disposed to adjoin each other by the foreign substance P, and the first electrode 131 and the second electrode 133 are deformed by a high electric current, such that the first electrode 131 and the second electrode 133 can be spaced apart from each other. In this case, the high-resistance portion 131b, in which the electrical connection is substantially blocked by resistance heat, is formed on the first electrode 131. Therefore, even though the first electrode 131 and the second electrode 133 adjoin each other again as the first electrode 131 and the second electrode 133 are not spaced apart from each other even after the repair process or the second electrode 133 is pushed during the process of joining the upper substrate 150 after the repair process, the second electrode 133 is disposed to adjoin the high-resistance portion 131b of the first electrode 131, such that the electrical disconnection between the first electrode 131 and the second electrode 133 can be maintained.

Therefore, it is possible to minimize the problem in which the repair fails because the first electrode 131 and the second electrode 133 are not spaced apart from each other even after the repair process or the first electrode 131 and the second electrode 133 are short-circuited again as the second electrode 133 is pushed. Therefore, in the display device 100 according to the embodiment of the present disclosure, the first electrode 131 is configured such that the high-resistance portion 131b, which is partially electrically disconnected during the repair process, is disposed. Therefore, it is possible to minimize the problem in which the repair fails because the second electrode 133 is pushed during the repair process related to the foreign substance defect, and it is possible to improve the reliability of the repair process related to the foreign substance defect.

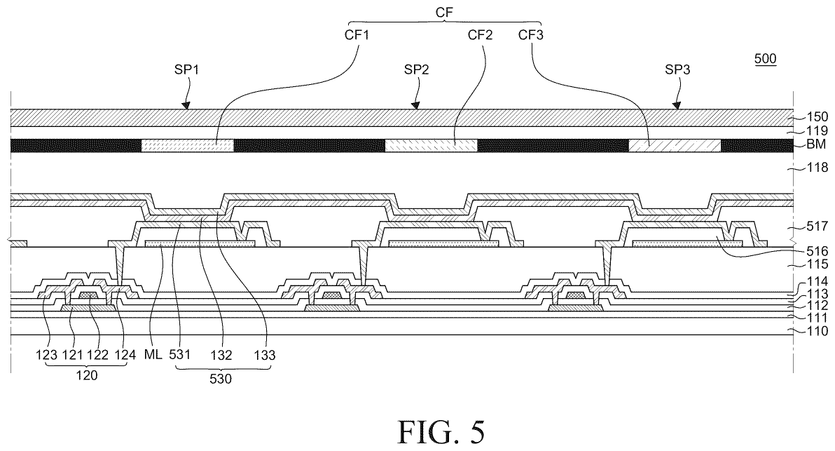

FIG. 5 is a cross-sectional view of a display device according to another embodiment of the present disclosure. A display device 500 in FIG. 5 is substantially identical in configuration to the display device 100 in FIGS. 1 to 4B, except that the reflective layer ML and a first electrode 531 are electrically connected. Therefore, repeated descriptions of the identical components will be omitted or may be briefly provided.

With reference to FIG. 5, an organic light-emitting element 530 including the first electrode 531, the light-emitting part 132, and the second electrode 133 is disposed on the reflective layer ML. The reflective layer ML and the first electrode 531 are spaced apart from each other by an insulation layer 516. The reflective layer ML and the first electrode 531 are disposed to be electrically connected. The first electrode 531 is disposed on a top surface of the reflective layer ML exposed through a contact hole formed in the insulation layer 516. In this case, the contact holes through which the reflective layer ML and the first electrode 531 contacted can be disposed to overlap a bank 517. For example, the contact holes through which the reflective layer ML and the first electrode 531 contacted can be disposed so as not to overlap a light-emitting area defined by the bank 517 in the organic light-emitting element 530. However, the present disclosure is not limited thereto.

In the display device 500 according to another embodiment of the present disclosure, the reflective layer ML and the first electrode 531 are disposed to be spaced apart from each other by the insulation layer 516. Therefore, the reflective layer ML may not be damaged during the repair process.

Specifically, the first electrode 531 and the reflective layer ML can be spaced apart from each other by the insulation layer 516. Therefore, the reflective layer ML may not be damaged during the process of disposing the high-resistance portion on the first electrode 531. For example, in case that the first electrode 531 is disposed on the reflective layer ML so as to be in direct contact with the reflective layer ML, the reflective layer ML, which is in contact with the first electrode 531, can be deformed by resistance heat generated when the high electric current is concentrated on the portion where the second electrode 133 and the first electrode 531 are in contact with each other during the R2-aging process, and the light reflection properties of the reflective layer ML can be degraded. In this case, in the display device 500 according to another embodiment of the present disclosure, the first electrode 531 and the reflective layer ML are spaced apart from each other, and the reflective layer ML does not adjoin the second electrode 133, which can minimize damage to the reflective layer ML during the repair process.

Meanwhile, in the display device 500 according to another embodiment of the present disclosure, the reflective layer ML and the first electrode 531 can be disposed to be electrically connected through the contact hole formed in the insulation layer 516. Therefore, it is possible to improve the electrical properties of the first electrode 531 by reducing resistance of the first electrode 531. The reflective layer ML and the first electrode 531 are disposed to be spaced apart from each other by the insulation layer 516 so that the reflective layer ML is not damaged during the repair process. In this case, the reflective layer ML and the first electrode 531 can be disposed to be electrically connected through the contact hole formed in the insulation layer 516. Therefore, even though the reflective layer ML and the first electrode 531 are disposed to be spaced apart from each other, the reflective layer ML and the first electrode 531 can be disposed to be electrically connected through the contact hole formed in the insulation layer 516, such that resistance of the first electrode 531 electrically connected to the reflective layer ML can be reduced, thereby improving the electrical properties of the first electrode 531.

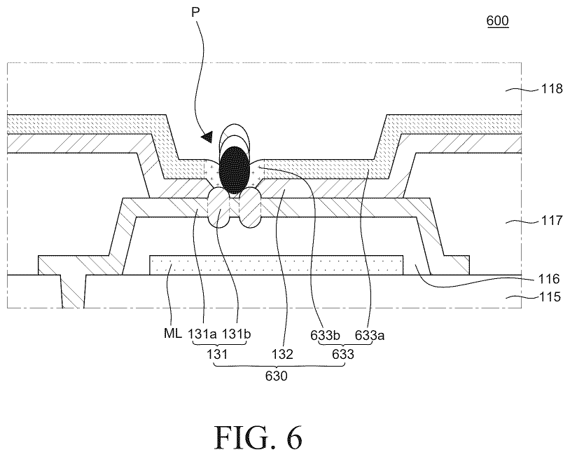

FIG. 6 is a cross-sectional view of a display device according to still another embodiment of the present disclosure. A display device 600 in FIG. 6 is substantially identical in configuration to the display device 100 in FIGS. 1 to 4B, except for a material of a second electrode 633. Therefore, repeated descriptions of the identical components will be omitted or briefly provided. Meanwhile, FIG. 6 illustrates a portion that has been subjected to the repair process because foreign substances are produced in the display device 600. A portion, where no foreign substance is produced, can be identical to that of the display device 100 in FIGS. 1 to 4B.

Referring to FIG. 6a, a second electrode 633 can be made of a material including indium (In). For example, the second electrode 633 can be made of a transparent conductive material such as indium-tin-oxide (ITO) or indium-zinc-oxide (IZO). However, the present disclosure is not limited thereto.

The second electrode 633 can be configured to be partially electrically disconnected and thus serve as a repair part that repairs the subpixel SP with a foreign substance defect.

In case that the foreign substance P is attached to the top surface of the first electrode 131 during the process of manufacturing the display device 600, the second electrode 633 can also be disposed on the top surface of the first electrode 131 exposed by the light-emitting part 132. Therefore, because the first electrode 131 and the second electrode 633 are in contact with each other and electrically connected to each other, a short circuit can occur when the display device operates. Therefore, the process of repairing the second electrode 633 connected to the first electrode 131 is performed during the process of manufacturing the display device 600. For example, the process of repairing the second electrode 633 connected to the first electrode 131 can use an R2-aging method that separates the first electrode 131 and the second electrode 633 by deforming the first electrode 131 and the second electrode 633 by using a high electric current concentrated on a portion where the second electrode 633 and the first electrode 131 are in contact with each other by applying a high voltage to the second electrode 633.

In this case, because resistance heat (Joule heating) is generated by a concentrated high electric current in a portion where the second electrode 633 and the first electrode 131 are in contact with each other, the high-resistance portion 131b can be formed on the first electrode 131, and a second resistance portion 633b can be formed on the second electrode 633. The high-resistance portion 131b and the second resistance portion 633b can be formed by a process in which a diffusion phenomenon in which distances between indium (In) particles included in the first electrode 131 and the second electrode 633 are increased by a high temperature occurs and a volume of the corresponding portion is also increased. In this case, a portion of the first electrode 131, where the high-resistance portion 131b is not formed, can be referred to as a low-resistance portion 131a. Further, a portion of the second electrode 633, where the second resistance portion 633b is not formed, can be referred to as a first resistance portion 633a.

Meanwhile, a thickness of the high-resistance portion 131b can be larger than a thickness of the low-resistance portion 131a. A thickness of the second resistance portion 633b can be larger than a thickness of the first resistance portion 633a. The thickness of each of the high-resistance portion 131b and the second resistance portion 633b can be increased by about 10% to 20% in comparison with each of the low-resistance portion 131a and the first resistance portion 633a. However, the present disclosure is not limited thereto.

In addition, an indium (In) density of the high-resistance portion 131b, which is a portion where the distances between the indium (In) particles are increased, can be lower than an indium density (In) of the low-resistance portion 131a. Further, an indium (In) density of the second resistance portion 633b, which is a portion where the distances between the indium (In) particles are increased, can be lower than an indium density (In) of the first resistance portion 633a. For example, the indium (In) density of the low-resistance portion 131a can be higher than the indium (In) density of the high-resistance portion 131b, and the indium (In) density of the first resistance portion 633a can be higher than the indium (In) density of the second resistance portion 633b.

In the display device 600 according to still another embodiment of the present disclosure, the electrical connection of the first electrode 131 and the second electrode 633 can be partially blocked, which can further improve the reliability of the repair process related to the foreign substance defect.

Specifically, the first electrode 131 and the second electrode 633 can each be made of a transparent conductive oxide including indium (In). Further, the process of repairing the A-C short circuit, which can be caused when the first electrode 131 and the second electrode 633 adjoin each other by the foreign substance P, is performed by applying a high voltage to the second electrode 633 during the process of manufacturing the display device 600. In this case, a high electric current can be concentrated between the first electrode 131 and the second electrode 633 disposed to adjoin each other by the foreign substance P, and the first electrode 131 and the second electrode 633 are deformed by a high electric current, such that the first electrode 131 and the second electrode 633 can be spaced apart from each other. In this case, the high-resistance portion 131b and the second resistance portion 633b, in which electrical connection is substantially blocked by resistance heat, are formed on the first electrode 131 and the second electrode 633. Therefore, even though the first electrode 131 and the second electrode 633 adjoin each other again as the first electrode 131 and the second electrode 633 are not spaced apart from each other even after the repair process or the second electrode 633 is pushed during the process of joining the upper substrate 150 after the repair process, the second resistance portion 633b of the second electrode 633 is disposed to adjoin the high-resistance portion 131b of the first electrode 131, such that the electrical disconnection between the first electrode 131 and the second electrode 633 can be maintained. Therefore, it is possible to minimize the problem in which the repair fails because the first electrode 131 and the second electrode 633 are not spaced apart from each other even after the repair process or the second electrode 633 and the first electrode 131 are short-circuited again as the second electrode 133 is pushed. Therefore, in the display device 600 according to still another embodiment of the present disclosure, the electrical connection of the first electrode 131 and the second electrode 633 can be partially blocked, which can further improve the reliability of the repair process related to the foreign substance defect.

The example embodiments of the present disclosure can also be described as follows:

According to an aspect of the present disclosure, a display device can include: a substrate; a transistor disposed on the substrate; an overcoating layer disposed on the transistor; a reflective layer disposed on the overcoating layer; an insulation layer disposed on the overcoating layer and the reflective layer; and an organic light-emitting element disposed on the insulation layer, electrically connected to the transistor, and including an anode, a light-emitting part, and a cathode, in which the anode is made of a transparent conductive oxide and is a conductor as a whole.

The insulation layer can cover a side surface and a top surface of the reflective layer.

An outer periphery of a top surface of the overcoating layer can be exposed by the reflective layer and the insulation layer.

The anode can cover a side surface and a top surface of the insulation layer. The anode can be in direct contact with the transistor.

The reflective layer can be electrically floated. The anode can be electrically connected to the reflective layer through a contact hole formed in the insulation layer.

The anode can include indium (In). The cathode can include indium (In).

According to another aspect of the present disclosure, a display device can include: a substrate; a transistor disposed on the substrate; an overcoating layer disposed on the transistor; a reflective layer disposed on the overcoating layer; an insulation layer disposed on the overcoating layer and the reflective layer; and an organic light-emitting element disposed on the insulation layer, electrically connected to the transistor, and including an anode, a light-emitting part, and a cathode, in which the anode is made of a transparent conductive oxide and includes a low-resistance portion, and a high-resistance portion having a higher resistance value than the low-resistance portion.

The high-resistance portion can be disposed to surround at least a part of a periphery of a foreign substance disposed on the anode.

A thickness of the high-resistance portion can be larger than a thickness of the low-resistance portion.

The anode can include indium, and an indium density of the low-resistance portion can be higher than an indium density of the high-resistance portion.

The cathode can have an opening portion that overlaps the high-resistance portion. The cathode can be disposed on the anode and can space apart from the anode. The cathode can adjoin the high-resistance portion.

The insulation layer can cover a side surface and a top surface of the reflective layer.

An outer periphery of a top surface of the overcoating layer can be exposed by the reflective layer and the insulation layer.

The anode can cover a side surface and a top surface of the insulation layer. The anode can be in direct contact with the transistor.

The reflective layer can be electrically floated. The anode can be electrically connected to the reflective layer through a contact hole formed in the insulation layer. The cathode can include indium (In).

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a substrate;
a transistor disposed on the substrate;
an overcoating layer disposed on the transistor;
a reflective layer disposed on the overcoating layer;
an insulation layer disposed on the overcoating layer and the reflective layer; and
an organic light-emitting element disposed on the insulation layer, electrically connected to the transistor, and comprising an anode, a light-emitting part, and a cathode,
wherein the anode is made of a transparent conductive oxide and is a conductor as a whole.

2. The display device of claim 1, wherein the insulation layer covers a side surface and a top surface of the reflective layer.

3. The display device of claim 1, wherein an outer periphery of a top surface of the overcoating layer is exposed by the reflective layer and the insulation layer.

4. The display device of claim 1, wherein the anode covers a side surface and a top surface of the insulation layer.

5. The display device of claim 1, wherein the anode is in direct contact with the transistor.

6. The display device of claim 1, wherein the reflective layer is electrically floated.

7. The display device of claim 1, wherein the anode is electrically connected to the reflective layer through a contact hole formed in the insulation layer.

8. The display device of claim 1, wherein at least one of the anode and the cathode includes indium.

9. The display device of claim 1, wherein the anode and the reflective layer are spaced apart from each other and electrically insulated by the insulation layer.

10. A display device comprising:
a substrate;
a transistor disposed on the substrate;
an overcoating layer disposed on the transistor;
a reflective layer disposed on the overcoating layer;
an insulation layer disposed on the overcoating layer and the reflective layer; and
an organic light-emitting element disposed on the insulation layer, electrically connected to the transistor, and comprising an anode, a light-emitting part, and a cathode,
wherein the anode is made of a transparent conductive oxide and comprises a low-resistance portion and a high-resistance portion having a higher resistance value than the low-resistance portion.

11. The display device of claim 10, wherein the high-resistance portion is disposed to surround at least a part of a periphery of a foreign substance disposed on the anode.

12. The display device of claim 10, wherein a thickness of the high-resistance portion is larger than a thickness of the low-resistance portion.

13. The display device of claim 10, wherein the anode includes indium, and an indium density of the low-resistance portion is higher than an indium density of the high-resistance portion.

14. The display device of claim 10, wherein the cathode has an opening portion that overlaps with the high-resistance portion.

15. The display device of claim 14, wherein the cathode is disposed on the anode and spaced apart from the anode.

16. The display device of claim 14, wherein the cathode adjoins the high-resistance portion.

17. The display device of claim 10, wherein the insulation layer covers a side surface and a top surface of the reflective layer.

18. The display device of claim 10, wherein an outer periphery of a top surface of the overcoating layer is exposed by the reflective layer and the insulation layer.

19. The display device of claim 10, wherein the anode covers a side surface and a top surface of the insulation layer.

20. The display device of claim 10, wherein the anode is in direct contact with the transistor.

21. The display device of claim 10, wherein the reflective layer is electrically floated.

22. The display device of claim 10, wherein the anode is electrically connected to the reflective layer through a contact hole formed in the insulation layer.

23. The display device of claim 10, wherein the cathode includes indium.

24. The display device of claim 10, wherein the anode and the reflective layer are spaced apart from each other and electrically insulated by the insulation layer.
